(19) United States
(12) Patent Application Publication
(10) Pub. No.: US 2003/0190829 A1
(43) Pub. Date: Oct. 9, 2003

(54) Dual damascene barrier structures and preferential etching method

(76) Inventor: Kenneth D. Brennan, Austin, TX (US)

Correspondence Address: TEXAS INSTRUMENTS INCORPORATED, P O BOX 655474, M/S 3999, DALLAS, TX, 75265

(21) Appl. No.: 10/117,486

(22) Filed: Apr. 5, 2002

(51) Int. Cl. H05K 1/00

(52) U.S. Cl. 439/200

(57) ABSTRACT

A multilevel metal interconnect structure and method of fabrication for semiconductor integrated circuits. A first horizontal metal interconnector line, for example copper, is topped by a stack of horizontal insulating layers alternating between etch stop and dielectric layers so that the bottom etch stop layer is selected to be etchable at a first rate by a selected etchant, while the upper etch stop layers are selected to be etchable at a second rate by the same selected etchant. Preferably, the first etch rate is about ten times faster than the second etch rate. When a vertical trench and via are etched into the stack, the bottom stop layer can be opened for contact to the first metal line without etching the other stop layers substantially. Trench and via are finally filled with metal, for instance copper, to form the second level interconnector line and the via contact to the first level metal line.

### FIELD OF THE INVENTION

The present invention is related in general to the field of electronic systems and semiconductor devices, and more specifically to structures and processes in integrated circuit fabrication aiming at interconnected multi-level copper metallization.

### DESCRIPTION OF THE RELATED ART

In the last few years, copper interconnection has been adapted to silicon integrated circuits due to its low resistance and high electromigration reliability compared to the traditional aluminum interconnection. Single-damascene and dual-damascene methods have been employed for the fabrication of copper interconnection. For multi-level copper interconnects using any of these two methods, improved electromigration reliability, especially improved lifetime of early failures have been reported, for example, in the recent article “A High Reliability Copper Dual-Damascene Interconnection with Direct-Contact Via Structure” (K. Ueno et al, IEEE Internat. Electron Devices Meeting Dec. 10-13, 2000, pp. 265-268). In the technique described, the improvement in multi-level copper circuits has been achieved by making the copper contacts on the bottom of interconnecting vias barrier-free except for an ultra-thin adhesion layer.

In spite of progress such as described in that paper, in known technology many problems still remain related to the copper interconnection concept. For example, the copper traces have to be sealed by barrier layers in order to prevent copper migration into the silicon circuitry where copper atoms are known to offer energy levels for electron recombination/generation, acting as electron life-time killers. The same sealing barriers should protect the porous insulating layers of low dielectric constant (so-called low-k materials) against intruding atoms, which may initiate coalescence of micro-voids into larger voids.

As an additional example, in the preparation process of copper-filled vias, care has to be taken to prepare the via linings so that copper resistivity is prevented from increasing inordinately when the via diameter is shrinking. Some progress in this direction has been described recently in U.S. patent application Ser. No. 60/247,650, filed on Nov. 9, 2000 (Qing-Tang Jiang, “Reducing Copper Line Resistivity by Smoothing Trench and Via Sidewalls”). No attention has been given, however, to practical methods such as whether the via fabrication steps are cost-effective and simple enough for easy clean-up after via preparation.

As another example, in any etching method of multi-level metal and dielectric structures, the dilemma arises how to continue the etching process without affecting prior etch barriers. Some progress towards a solution has been described recently in U.S. patent applications Ser. No. 09/863,687, filed on May 23, 2001 (Brennan et al., “Method for Sealing Vie Sidewalls in Porous Low-k Dielectric Layers”), and Ser. No. 09/917,364, filed on Jul. 27, 2001 (Brennan et al., “Method of Fabricating Interlevel Connectors using only one Photomask Step”). However, the etching methods are precarious and a satisfactory combination of barrier structure and etching method is still missing.

An urgent need has, therefore, arisen for a coherent, low-cost method of fabricating copper-filled via interconnection in dual damascene copper metallization in the presence of multilevel dielectrics and barrier layers, and, simultaneously, improve the degree of component reliability. The fabrication method should be simple, yet flexible enough for different semiconductor product families and a wide spectrum of design and process variations. Preferably, these innovations should be accomplished without extending production cycle time, and using the installed equipment, so that no investment in new manufacturing machines is needed.

### SUMMARY OF THE INVENTION

The invention describes a multilevel metal interconnect structure and method of fabrication for semiconductor integrated circuits. A first horizontal metal interconnector line, for example copper, is topped by a stack of horizontal insulating layers alternating between etch stop and dielectric layers so that the bottom etch stop layer is selected to be etchable at a first rate by a selected etchant, while the upper etch stop layers are selected to be etchable at a second rate by the same selected etchant. Preferably, the first etch rate is about ten times faster than the second etch rate. When a vertical trench and via are etched into the stack, the bottom stop layer can be opened for contact to the first metal line without etching the other stop layers substantially. Trench and via are finally filled with metal, for instance copper, to form the second level interconnector line and the via contact to the first level metal line.

It is an aspect of the invention that the method is fully compatible with single damascene and dual damascene process flow and deep sub-micron (0.18 ∞m and smaller) technologies.

In the preferred embodiment of the invention, the stack of insulating layers comprises three etch stop layers alternating with two dielectric layers. The bottom stop layer is preferably made of silicon carbon nitride or silicon nitride in the thickness range from 50 to 75 nm, the top stop layers are preferably made of silicon carbide in the thickness range from 30 to 50 nm. The dielectric layers are preferably porous low-k materials in the thickness range from 200 to 400 nm.

The preferential etch for the stop layers comprises a plasma consisting of CH3F, argon and oxygen, which etches silicon carbon nitride 150 nm/min and silicon carbide at 15 nm/min.

It is an aspect of the invention that the method is fully compatible with single damascene and dual damascene process flow and deep sub-micron (0.18 μm and smaller) technologies.

Another aspect of the invention is that it applicable to a wide variety of circuits and process technologies. Examples of semiconductor device families include DRAMs, standard linear and logic products, digital signal processors, microprocessors, digital and analog devices, high frequency and high power devices and both large and small are chip categories.

The preferred metallization is copper; the invention is applicable, however, to a variety of metals. The invention can further be applied to any circuit where metal level-to-level interconnects are presently built with two photomasks and a process reduction to only one mask represents an economical advantage.

The technical advances represented by the invention, as well as the aspects thereof, will become apparent from the following description of the preferred embodiments of the invention, when considered in conjunction with the accompanying drawings and the novel features set forth in the appended claims.

### BRIEF DESCRIPTION OF THE DRAWINGS

FIG. 1 shows a schematic cross section through a stack of insulating layers, alternating between etch stop and dielectric layers, over the (n−1) level metal line.

FIG. 2 shows the schematic cross section after the via has been etched through the top etch stop and the top dielectric layer.

FIG. 3 shows the schematic cross section after the trench has been etched, while the via has been etched to the bottom stop layer.

FIG. 4 shows the schematic cross section after continued etching according to the preferential etch rates of the etchant is applied to the bottom stop layer according to the invention.

FIG. 5 is a schematic cross section of the metal filling of the (n−1) and the (n) levels.

FIG. 6 shows schematically the application of the invention to another embodiment.

### DETAILED DESCRIPTION OF THE PREFERRED EMBODIMENTS

The present invention is related to U.S. patent applications Ser. No. 09/863,687, filed on May 23, 2001 (Brennan et al., “Method for Sealing Via Sidewalls in Porous Low-k Dielectric Layers”); Ser. No. 09/917,364, filed on Jul. 27, 2001 (Brennan et al., “Method of Fabricating Interlevel Connectors using only one Photomask Step”); Ser. No. 09/975,571, filed on Oct. 11, 2001 (Jiang, “Reducing Copper Line Resistivity by Smoothing Trench and Via Sidewalls”); and TI Ser. No. 32156, filed on Mar. 27, 2002 (Jiang et al., “Copper Transition Layer for Improving Copper Interconnection Reliability”).

Single-damascene and dual-damascene processes have been used to fabricate copper interconnections. This invention applies to both of these technologies. The dual-damascene technology has the advantage of reducing process steps which leads to lower cost. It is, therefore, chosen as the vehicle to describe the present invention. It should be stressed, however, that this invention applies also to the single-damascene technology.

FIG. 1 is a schematic representation of a dual-damascene interlevel structure, generally designated 100; FIG. 1 is generic and not to scale. A first level horizontal metal interconnector line has been produced, located on, or imbedded in, an insulated semiconductor substrate 102. This level of metallization is marked as (n−1) level in order to indicate that a multi-level hierarchy of metal levels is considered. In this invention, line 101 is made of copper.

Positioned over metal line 101 is a first horizontal insulating layer 103, which operates as a first etch stop layer. It is also referred to as “via etch stop” layer. It is pivotally important for the present invention that this first etch stop 103 is made of a material which is etchable by a selected etchant at a first rate.

The preferred selection for the first etch stop is a layer made of silicon carbon nitride, silicon nitride, any other nitride-containing silicon compound, or silicon carbon oxide in the thickness range from 50 to 75 nm.

The preferred selection as etchant is a plasma initiated in a gas mixture of controlled amounts of a saturated carbon hydride halogen constituent, an inert constituent, and an oxidizing constituent. A preferred selection of gases and amounts are the following:

Saturated carbon hydride halogen constituent: a gaseous compound selected from a group consisting of a first portion as methyl, ethyl, propyl, and butyl, and a second portion as fluorine, chlorine, bromine, and iodine. Preferred examples are CH3F (methyl fluoride, fluorocarbon), C2H2F, or CHF3. The amount of saturated carbon hydride halogen constituent in the gas mixture is preferably 40 parts.

Inert constituent: a gaseous compound selected from a group consisting of nitrogen, helium, neon, argon, krypton, and xenon. The amount of inert constituent in the gas mixture is preferably 100 parts.

Oxidizing constituent: a gaseous component, preferably oxygen or fluorine. The amount of oxidizing constituent in the gas mixture is preferably 10 to 20 parts.

The plasma is initiated in the gas mixture under an RF power of preferably between 200 and 300 W, which represents a 25 to 50% reduction compared to standard plasma conditions.

For the plasma of a gas mixture and the reduced power as described above, the etch rate of the nitride-containing silicon compound used for stop layer 103 is approximately 150 nm/min. This high first etch rate value of the first etch stop 103 is of crucial importance for the other material selections of the structure in FIG. 1.

Over etch stop layer 103 is the via-level dielectric 104. When a porous, low dielectric constant material is selected, a preferred thickness range is between 250 and 500 nm. Commercially materials are available under the brand name XLK 2.2 by Dow Corning, USA, or SILK by Cow Chemical, USA, or LKD 5109 by JSR, Japan. Another example is CORAL by Novellus, USA.

Over the via-level dielectric 104 is the third insulating layer, the second etch stop layer 105, often referred to as Middle Stop Layer, or Trench Stop Layer. Preferred material is silicon carbide (nitride-free) in the thickness range from about 30 to 50 nm; the thinner end of this range is preferred.

For the plasma of a gas mixture and the reduced power as described above, the etch rate of the silicon carbide is approximately 15 nm/min. This ten times lower second etch rate value of the nitride-free second etch stop 105 is in clear contrast to the high etch rate value of the nitride-containing first etch stop 103.

Over the Trench Stop Layer 105 is another layer 106 of dielectric material, referred to as the fourth or trench-level dielectric. For a porous, low dielectric material such as XLK 2.2 by Dow Corning or JSR film LKD 5109, the preferred thickness range is between 300 and 500 nm.

A fifth insulating layer, the cap layer 107 completes the sequence of layers for this interlevel insulation stack. It is operable as an etch stop layer and selected so that its material is etchable at the second, low etch rate of the selected plasma etchant. Preferred material for the cap layer 107 is again nitride-free silicon carbide in the thickness range from 30 to 50 nm, or for other applications from 50 to 100 nm. (A second embodiment of the invention with a dual hard mask is described below).

A number of process flows have been developed to fabricate the (n)th level metal and connect it by metal-filled via to the (n−1) level. For purpose of illustrating the invention, a particular process flow is selected in FIGS. 1 to 5 to fabricate integrated circuit multi-level interconnects comprising horizontal trenches and vertical vias between metal lines. It should be stressed, however, that the invention also applies to alternative process flows.

FIG. 1: Forming first horizontal metal interconnector lines 101 (copper), on an insulated semiconductor substrate 102;

depositing the bottom first stop layer 103 over the first metal lines 101. Stop layer 103 consists of silicon carbon nitride, silicon nitride, or other nitride-containing compound, or silicon carbon oxide, 50 to 75 nm thick. First (via) stop layer 103 is selected to be etchable at a first rate (about 150 nm/min) by a selected etchant. This etchant is preferably a low RF power (200 to 300 W) plasma of a mixture (40:100:10) of a saturated carbon hydride halogen constituent (CH3F), an inert constituent (Ar), and an oxidizing constituent (O2);

depositing the first dielectric layer 104 over the bottom first stop layer 103. This via-level dielectric is a low-k dielectric, 300 to 500 nm thick;

depositing the second stop layer 105 over the first dielectric layer 104. The second (trench) stop layer consists of silicon carbide, 30 to 50 nm thick. Second stop layer is selected to be etchable at a second rate (about 15 nm/min) by the selected etchant;

depositing the second (trench level) dielectric layer 106 over the second stop layer 105; as a low-k dielectric, the thickness is between 300 and 500 nm;

depositing the third stop layer 107 over the second dielectric layer 106. The third stop (hard mask or cap) layer consists of silicon carbide, 30 to 100 nm thick. Third stop layer selected to be etchable at the second rate (about 15 nm/min) by the selected etchant.

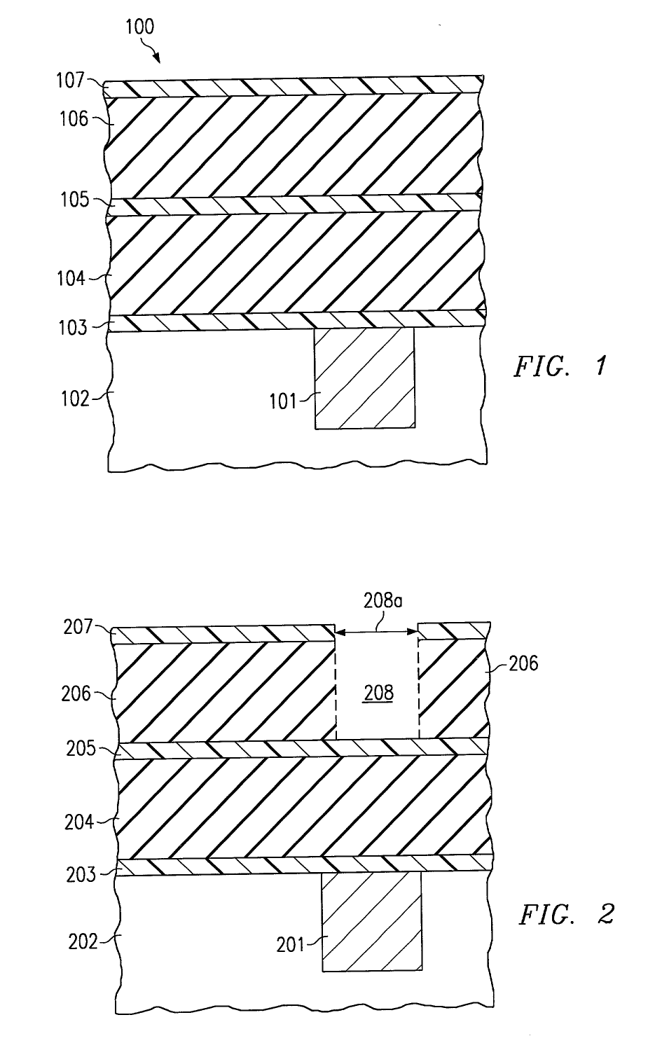

FIG. 2: Depositing a first photoresist layer (not shown in FIG. 2) over the third stop layer (207);

patterning the photoresist layer to create a plurality of holes, each hole having the dimensions defining the vias. The width of the via depends on the prevailing technology node; a preferred width is 0.18 μm;

using the selected etchant, etching into the third stop layer 207, at the second etch rate of 15 nm/min, for a period of time sufficient to remove all of the third stop layer 207 and second dielectric layer 206, thereby defining the vias 208 of width 208a in the second dielectric layer 206;

stripping the first photoresist layer.

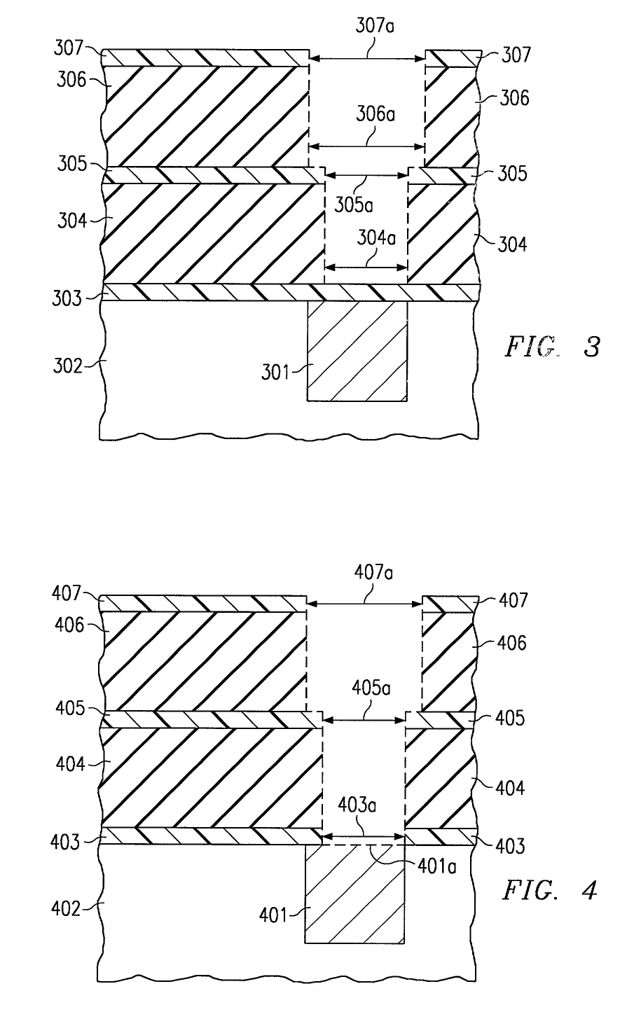

FIG. 3: Depositing a second photoresist layer (not shown in FIG. 3) over the remainder of the third stop layer (207 in FIG. 2);

patterning the photoresist layer to create a plurality of openings nested around the defined vias and having the outline of each of the trenches;

using the selected etchant, etching into the third stop layer 307, at the second etch rate of 15 nm/min for a period of time sufficient to remove all/of the third stop layer (opening 307a) and the second dielectric layer 306 opening 306a), thereby defining the trenches (width 306a, typically 0.2 μm) in the second dielectric layer 306, while concurrently continuing to etch the via completely through the second stop layer 305 (width 305a) and the first dielectric layer 304 (width 304a).

FIG. 4: Continuing using said selected etchant, etching the via into the first stop layer 403, at the first etch rate of 150 nm/min, for a period of time sufficient to remove all of the first stop layer 403 (opening 403a), thereby exposing the first metal line 401 in the via (surface 401a), while the second stop layer 405 and the third stop layer 407 are barely etched at 405a and 407a, respectively; these stop layers can thus continue to protect the porous low-k dielectric layers.

FIG. 5: Filling trench 510 and via 511 with metal (copper), thereby forming in the trench the second horizontal metal interconnector line (n level), and contact, by the via 511, the first metal 501 (n−1 level).

Partially removing the cap layer 507 during the chemical-mechanical polishing 520 of the copper-filled trench 510.

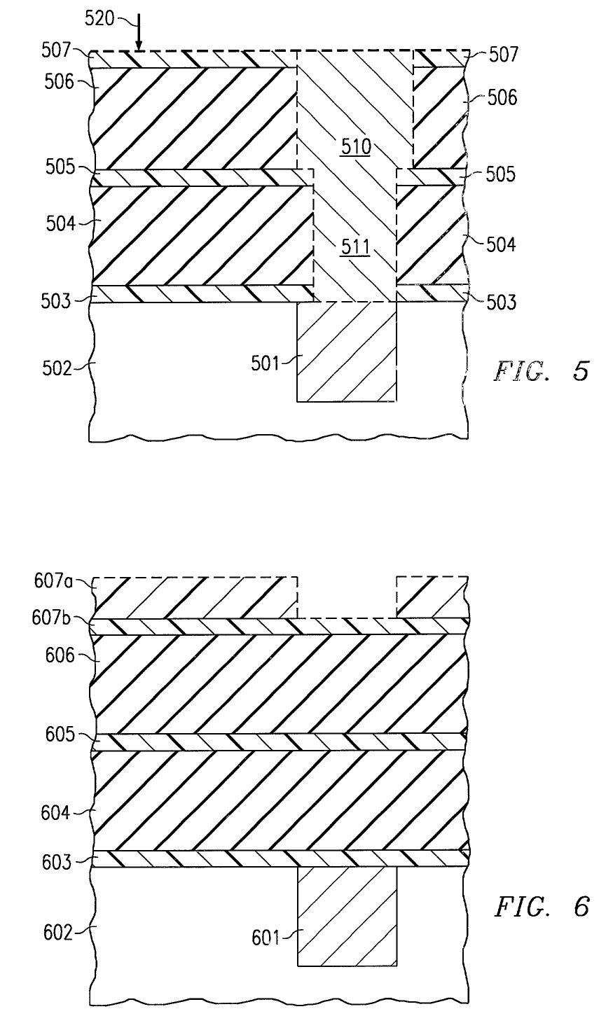

FIG. 6 indicates another embodiment of the invention. The third (top) stop layer comprises two insulating layers, the top layer 607a and the bottom layer 607b. Such double stop layer is frequently referred to as dual hard mask. The top layer 607a is preferably silicon carbon nitride or silicon nitride (thickness between 50 to 150 nm), the bottom layer 607b, in contrast, silicon carbide (thickness range from 30 to 50 nm). Consequently, these layers etch at the drastically different rates of 10:1 when the plasma etchant of the invention is used. This situation is indicated by FIG. 6, where the top layer 607a of the dial hard mask has been etch through, while the bottom layer 607b remains substantially unchanged.

These differential etch rates are useful, when, for example, the trench pattern is etched in the top layer of the hard mask. The subsequent via pattern may be misaligned to the trench pattern. A selective etch of at least 10:1 is required to open up the via pattern in the top layer of the hard mask stopping on the bottom layer of the hard mask.

It should be mentioned that the top layer 607a of the dual hard mask does not have to function as a moisture barrier; this function is performed by a separate silicon nitride layer on the very top of the multi-level metal hierarchy.

While this invention has been described in reference to illustrative embodiments, this description is not intended to be construed in a limiting sense. Various modifications and combinations of the illustrative embodiments, as well as other embodiments of the invention, will be apparent to persons skilled in the art upon reference to the description. An example is the repeated application of the preferential etch rate of the invention to the fabrication of each metal level of the multi-level hierarchies (7 or 8 levels of metal) of contemporary circuits. It is therefore intended that the appended claims encompass any such modifications or embodiments.

I claim:

1. A multilevel metal interconnect structure for semiconductor integrated circuits, comprising:
a first level horizontal metal interconnector lines, on an insulated semiconductor substrate;
a first horizontal insulating layer over said metal line, said first insulating layer operable as first etch stop and selected to be etchable at a first rate by a selected etchant;
a second insulating layer operable as first circuit dielectric over said first insulator;
a third insulating layer over said second insulator, said third insulating layer operable as second etch stop and selected to be etchable at a second rate by said selected etchant;
a fourth insulating layer operable as second circuit dielectric over said third insulator;
a fifth insulating layer over said fourth insulator, said fifth insulating layer operable as third etch stop and selected to be etchable at said second rate by said selected etchant;
a trench approximately vertically oriented through said third etch stop and said second dielectric;
a via approximately vertically oriented and aligned with said trench, through said first dielectric and said first etch stop; and
said trench and said via filled with metal so that said metal in said trench forms the second level interconnector line, and said metal in said via contacts said first level metal line.

2. The structure according to claim 1 wherein said metal and metal lines are copper.

3. The structure according to claim 1 wherein said first insulating layer is made of silicon carbon nitride, silicon nitride, any other nitride-containing silicon compound, or silicon carbon oxide in the thickness range from 50 to 75 nm.

4. The structure according to claim 1 wherein said second and fourth dielectric layer are porous low-k dielectric materials in the thickness range from 250 to 500 nm.

5. The structure according to claim 1 wherein said third and fifth insulating layers are made of silicon carbide in the thickness range from 30 to 50 nm.

6. The structure according to claim 1 further comprising a sixth insulating layer topping said fifth insulating layer, said sixth insulating layer made of silicon carbo nitride or silicon nitride in the thickness range from 50 to 150 nm. Alternatively, the fifth insulating layer, made of silicon carbide, may have a thickness range from 50 to 100 nm.

7. A method of fabricating integrated circuit multi-level interconnects comprising horizontal trenches and vertical vias between metal lines, comprising the steps of:
forming first horizontal metal interconnector lines on an insulated semiconductor substrate;
depositing the bottom first stop layer over said first metal lines, said first stop layer selected to be etchable at a first rate by a selected etchant;
depositing the first dielectric layer over said bottom first stop layer;
depositing the second stop layer over said first dielectric layer, said second stop layer selected to be etchable at a second rate by said selected etchant;
depositing the second dielectric layer over said second stop layer;
depositing the third stop layer over said second dielectric layer, said third stop layer selected to be etchable at said second rate by said selected etchant said third stop layer being the top layer;
depositing a first photoresist layer over said third stop layer;
patterning said photoresist layer to create a plurality of holes, each hole having the dimensions defining said vias;
using said selected etchant, etching into said third stop layer, at said second etch rate, for a period of time sufficient to remove all of said third stop layer and said second dielectric layer, thereby defining said vias in said second dielectric layer;
stripping said first photoresist layer;
depositing a second photoresist layer over the remainder of said third stop layer;
patterning said photoresist layer to create a plurality of openings nested around said defined vias and having the outline of each of said trenches;
using said selected etchant, etching into said third stop layer, at said second etch rate, for a period of time sufficient to remove all of said third stop layer and said second dielectric layer, thereby defining said trenches in said second dielectric layer, while concurrently continuing to etch said via completely through said second stop layer and said first dielectric layer;
continuing using said selected etchant, etching said via into said first stop layer, at said first etch rate, for a period of time sufficient to remove all of said first stop layer, thereby exposing said first metal line in said via, while said second and third stop layers are barely etched; and
filling said trench and said via with metal, thereby forming in the trench the second horizontal metal interconnector line and contact, by the via, the first metal.

8. The method according to claim 7 wherein said metal is copper.

9. The method according to claim 7 wherein said first stop layer is made of silicon carbon nitride, silicon nitride, any other nitride-containing silicon compound, or silicon carbon oxide in the thickness range from 50 to 75 nm.

10. The method according to claim 7 wherein said first and second dielectric layers are porous low-k dielectric materials in the thickness range from 300 to 500 nm.

11. The method according to claim 7 wherein said second and third stop layer are silicon carbide in the thickness range from 30 to 50 nm.

12. The method according to claim 7 wherein said selected etchant comprises:
a gas mixture of controlled amounts of a saturated carbon hydride halogen constituent, an inert constituent, and an oxidizing constituent; and
a plasma initiated in said gas mixture under an RF power reduced compared to standard plasma conditions.

13. The method according to claim 12 wherein said saturated carbon hydride halogen constituent is a gaseous compound selected from a group consisting of a first portion as methyl, ethyl, propyl, and butyl, and a second portion as fluorine, chlorine, bromine, and iodine.

14. The method according to claim 13 wherein the amount of said saturated carbon hydride halogen constituent in said gas mixture is preferably 40 parts.

15. The method according to claim 12 wherein said saturated carbon hydride halogen constituent is CH3F (methyl fluoride, fluorocarbon).

16. The method according to claim 12 wherein said saturated carbon hydride halogen is C2H2F or CHF3.

17. The method according to claim 12 wherein said inert constituent is selected from a group consisting of nitrogen, helium, neon, argon, krypton, and xenon.

18. The method according to claim 17 wherein the amount of said inert constituent in said gas mixture is preferably 100 parts.

19. The method according to claim 12 wherein said oxidizing constituent is selected from a group consisting of oxygen and fluorine.

20. The method according to claim 19 wherein the amount of said oxidizing constituent in said gas mixture is preferably between 10 and 20 parts.

21. The method according to claim 12 wherein said reduced RE power is between 200 and 300 W, representing a 25 to 50% reduction compared to standard plasma conditions.

22. The method according to claim 12 wherein said first etch rate is approximately 150 nm/min.

23. The structure according to claim 12 wherein said second etch rate is approximately 15 nm/min.
